(19) United States
(12) Patent Application Publication
(10) Pub. No.: US 2026/0237550 A1
(43) Pub. Date: Aug. 13, 2026

(54) METAL MAGNETIC THIN FILM

(71) Applicant: Murata Manufacturing Co., Ltd., Kyoto-fu (JP)

(72) Inventors: Kenji SAKAGUCHI, Nagaokakyo-shi (JP); Kojiro KOMAGAKI, Nagaokakyo-shi (JP); Masashi HATTORI, Nagaokakyo-shi (JP)

(73) Assignee: Murata Manufacturing Co., Ltd., Kyoto-fu (JP)

(21) Appl. No.: 19/632,913

(22) Filed: Mar. 30, 2026

Related U.S. Application Data
(63) Continuation of application No. PCT/JP2024/038743, filed on Oct. 30, 2024.

(30) Foreign Application Priority Data
Nov. 7, 2023 (JP) 2023-190289

(51) Int. Cl. H01F 27/24; H01F 1/147; H01F 41/18

(52) U.S. Cl. CPC H01F 27/24; H01F 1/14766; H01F 41/18

(57) ABSTRACT

A metal magnetic thin film comprising a plurality of columnar structures having an amorphous phase and whose longitudinal directions extend in a film thickness direction. The plurality of columnar structures each include a body portion and a sidewall portion continuous with the body portion. The plurality of columnar structures each contains Fe, Co, Si, and B. Also, in the sidewall portion, the total amount of the Fe and the Co is greater than the total amount of the Si and the B in terms of atomic percent concentration.

### CROSS REFERENCE TO RELATED APPLICATIONS

This application claims benefit of priority to International Patent Application No. PCT/JP2024/038743, filed Oct. 30, 2024, and to Japanese Patent Application No. 2023-190289, filed Nov. 7, 2023, the entire contents of each are incorporated herein by reference.

### BACKGROUND

### Technical Field

The present disclosure relates to a metallic magnetic thin film.

### Background Art

In recent years, there has been an increasing demand for high-frequency magnetic materials. Because high-frequency magnetic materials have high magnetic permeability in the high-frequency range, disposing such magnetic materials in the vicinity of certain electronic members can suppress the generation of unnecessary induced currents, thereby possibly stabilizing radio wave communications in the high-frequency range.

JP2009-059932A discloses a composite magnetic film as such a high-frequency magnetic material, which comprises a substrate, a magnetic phase formed on the substrate and forming a plurality of columns whose longitudinal direction is oriented perpendicular to the surface of the substrate, and an insulating phase that fills the gaps between the columns and has a relatively low proportion of magnetic metal elements in order to ensure electrical resistivity. Furthermore, the composite magnetic film of JP2009-059932A has in-plane uniaxial anisotropy, which makes it possible to reduce the loss component of magnetic permeability in the high-frequency range.

The inventors of the present application have found that there are some points that can be improved in the magnetic film of the above high-frequency magnetic material. Specifically, the insulating phase filling the gaps between the magnetic phases contains a relatively small amount of magnetic metal components. Therefore, it cannot be said that the magnetic film as a whole has a sufficiently high magnetic permeability, and as a result, it may not be possible to ensure a sufficiently high saturation magnetization.

### SUMMARY

The present disclosure has been conceived in consideration of the above circumstances, and provides a metal magnetic thin film that can achieve both in-plane uniaxial anisotropy and high saturation magnetization.

Accordingly, the present disclosure provides a metal magnetic thin film, comprising a plurality of columnar structures having an amorphous phase and whose longitudinal directions extend in a film thickness direction. The plurality of columnar structures each include a body portion and a sidewall portion continuous with the body portion. The plurality of columnar structures each contain Fe, Co, Si, and B. Also, in the sidewall portion, the total amount of the Fe and the Co is greater than the total amount of the Si and the B in terms of atomic percent concentration.

The metal magnetic thin film of the present disclosure enables achievement of both in-plane uniaxial anisotropy and high saturation magnetization.

### BRIEF DESCRIPTION OF DRAWINGS

FIG. 1 is a perspective view schematically showing a metal magnetic thin film of the present disclosure;

FIG. 2 is a perspective view schematically showing a columnar structure that is a constituent of the metal magnetic thin film of the present disclosure;

FIG. 3 is a plan view schematically showing the columnar structure that is a constituent of the metal magnetic thin film of the present disclosure;

FIG. 4 is a perspective view schematically showing a columnar structure in which a relatively large amount of B is present in a corner portion of a sidewall portion in terms of atomic % concentration;

FIG. 5 is a plan view schematically showing the columnar structure in which a relatively large amount of B is present in the corner portion of the sidewall portion in terms of atomic % concentration;

FIG. 6A shows a scanning transmission electron microscope (STEM) image along a surface at a predetermined location of the metal magnetic thin film of the present disclosure;

FIG. 6B is a graph showing the results of EDX line analysis of the metal magnetic thin film of the present disclosure;

FIG. 6C shows a scanning transmission electron microscope (STEM) image of a cross section along the thickness direction at a predetermined location of the metal magnetic thin film of the present disclosure;

FIG. 7A shows a scanning transmission electron microscope (STEM) image and elemental mapping image along a surface at a predetermined location of the metal magnetic thin film of the present disclosure;

FIG. 7B is a graph showing an EELS spectrum at a predetermined location on a surface of the metal magnetic thin film of the present disclosure;

FIG. 7C is a graph showing an EELS spectrum at a predetermined location on a surface of the metal magnetic thin film of the present disclosure;

FIG. 8 is a graph showing a magnetization curve of a laminate including the metal magnetic thin film according to the present disclosure;

FIG. 9 is a cross-sectional view schematically showing a laminate including the metal magnetic thin film according to the present disclosure;

FIG. 10A is a graph showing the magnetization curve of a metal magnetic thin film when the content of Co element is 0 at %;

FIG. 10B is a graph showing the magnetization curve of a metal magnetic thin film when the content of Co element is 10 at %;

FIG. 10C is a graph showing the magnetization curve of a metal magnetic thin film when the content of Co element is 30 at %;

FIG. 10D is a graph showing the magnetization curve of a metal magnetic thin film when the content of Co element is 50 at %;

FIG. 10E is a graph showing the magnetization curve of a metal magnetic thin film when the content of Co element is 100 at %;

FIG. 10F shows a scanning transmission electron microscope (STEM) image of a cross section along the thickness direction at a predetermined location of the metal magnetic thin film when the content of Co element is 50 at %;

FIG. 11A is a graph showing the magnetization curve of a heat-treated metal magnetic thin film in which the content of Co element is 0 at %;

FIG. 11B is a graph showing the magnetization curve of a heat-treated metal magnetic thin film in which the content of Co element is 10 at %;

FIG. 11C is a graph showing the magnetization curve of a heat-treated metal magnetic thin film in which the content of Co element is 30 at %;

FIG. 11D is a graph showing the magnetization curve of a heat-treated metal magnetic thin film in which the content of Co element is 50 at %;

FIG. 11E is a graph showing the magnetization curve of a heat-treated metal magnetic thin film in which the content of Co element is 100 at %;

FIG. 12A is a graph showing the behavior of a real part μ′ and an imaginary part μ″ of the complex permeability versus frequency in a metal magnetic thin film (film thickness: 40 nm/P content: 0 at %) of the present disclosure;

FIG. 12B is a graph showing the behavior of the real part μ′ and the imaginary part μ″ of the complex permeability versus frequency in a metal magnetic thin film (film thickness: 40 nm/P content: 2.0 at %) of the present disclosure;

FIG. 12C is a graph showing the behavior of the real part μ′ and the imaginary part μ″ of the complex permeability versus frequency in a metal magnetic thin film (film thickness: 40 nm/P content: 4.4 at %) of the present disclosure;

FIG. 12D is a graph showing the behavior of the real part μ′ and the imaginary part μ″ of the complex permeability versus frequency in a metal magnetic thin film (film thickness: 40 nm/P content: 7.1 at %) of the present disclosure;

FIG. 12E is a graph showing the behavior of the real part μ′ and the imaginary part μ″ of the complex permeability versus frequency in a metal magnetic thin film (film thickness: 40 nm/P content: 14.0 at %) of the present disclosure;

FIG. 13A is a graph showing the behavior of the real part μ′ and the imaginary part μ″ of the complex permeability versus frequency in a metal magnetic thin film (film thickness: 160 nm/P content: 0 at %) of the present disclosure;

FIG. 13B is a graph showing the behavior of the real part μ′ and the imaginary part μ″ of the complex permeability versus frequency in a metal magnetic thin film (film thickness: 160 nm/P content: 2.0 at %) of the present disclosure;

FIG. 13C is a graph showing the behavior of the real part μ′ and the imaginary part μ″ of the complex permeability versus frequency in a metal magnetic thin film (film thickness: 160 nm/P content: 4.4 at %) of the present disclosure;

FIG. 13D is a graph showing the behavior of the real part μ′ and the imaginary part μ″ of the complex permeability versus frequency in a metal magnetic thin film (film thickness: 160 nm/P content: 7.1 at %) of the present disclosure;

FIG. 13E is a graph showing the behavior of the real part μ′ and the imaginary part μ″ of the complex permeability versus frequency in a metal magnetic thin film (film thickness: 160 nm/P content: 14.0 at %) of the present disclosure;

FIG. 14A is a graph showing the behavior of the real part μ′ and the imaginary part μ″ of the complex permeability versus frequency when the metal magnetic thin film of the present disclosure includes an insulating film arranged between the metal magnetic thin films along the stacking direction;

FIG. 14B is a graph showing the behavior of the real part μ′ and the imaginary part μ″ of the complex permeability versus frequency when a metal magnetic thin film according to the present disclosure is disposed along the stacking direction, but no insulating film is disposed between the metal magnetic thin films;

FIG. 15 is a graph showing the magnetization curve of a laminate including a metal magnetic thin film according to the present disclosure;

FIG. 16 is a plan view schematically showing an electronic component including a metal magnetic thin film according to the present disclosure; and

FIGS. 17A to 17C are schematic diagrams illustrating a method for fabricating an electronic component including a metal magnetic thin film according to the present disclosure.

### DETAILED DESCRIPTION

A metal magnetic thin film of the present disclosure will now be described with reference to the drawings.

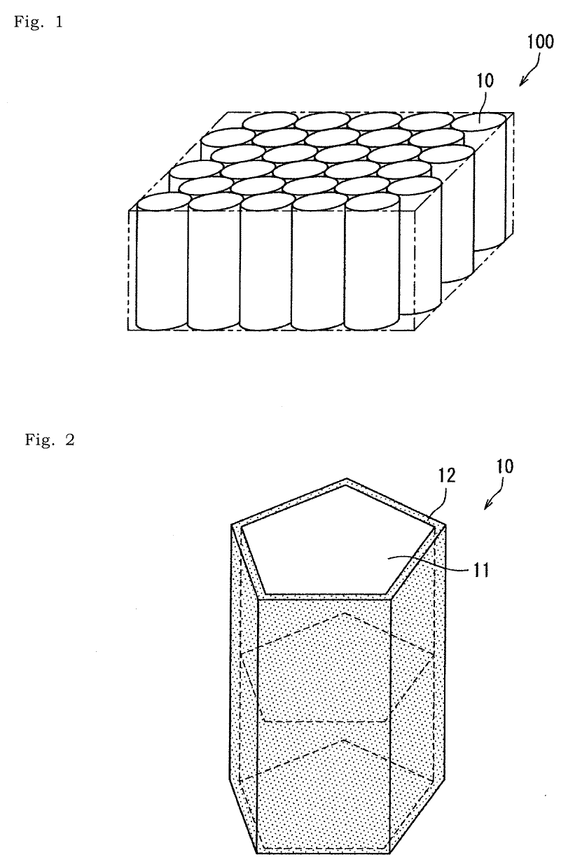

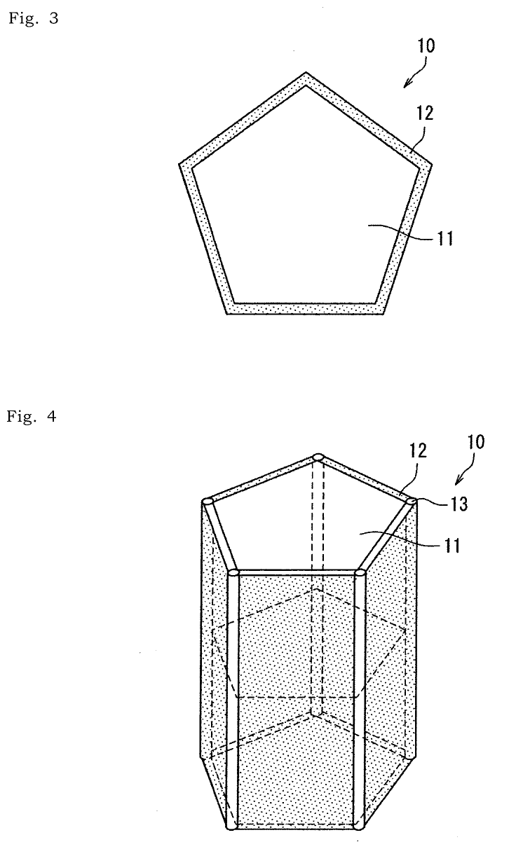

FIG. 1 is a perspective view schematically showing a metal magnetic thin film of the present disclosure, FIG. 2 is a perspective view schematically showing a columnar structure that is a constituent of the metal magnetic thin film of the present disclosure, and FIG. 3 is a plan view schematically showing a columnar structure that is a constituent of the metal magnetic thin film of the present disclosure.

A metal magnetic thin film 100 of the present disclosure includes a plurality of columnar structures 10 therein (see FIG. 1). The plurality of columnar structures 10 may be arranged so as to be continuous with or adjacent to one another. The columnar structures 10 are amorphous and have a configuration in which their longitudinal axes extend in the film thickness direction. The metal magnetic thin film 100 may be, for example, a sputtered film. Sputtering film formation is preferable in that it allows the production of a thin film with a composition ratio approximately identical to that of the target. Sputtering film formation is preferably performed with a magnetic field applied. Furthermore, if necessary, heat treatment in a magnetic field after film formation (e.g., time heat treatment at 3 kOe and 280° C.) can further reduce the coercive force Hc.

A columnar structure 10 includes a body portion 11 and a sidewall portion 12 continuous with the body portion 11 (see FIGS. 2 and 3). In a plurality of columnar structures 10, the sidewall portion 12 is continuous with the body portion 11 and is located between the body portions 11. The columnar structure 10 may contain Fe, Co, Si, and B. The columnar structure 10 may have a polygonal shape in plan view. For example, the planar shape of the columnar structure 10 may be a triangle, a rectangle, a pentagon, a hexagon, or the like. In this case, the polygonal planar shape allows the sidewall portion 12 of the columnar structure 10 to have a plurality of corner portions 13.

The metal magnetic thin film 100 may have an average thickness of 100 nm or more and 500 nm or less (i.e., from 100 nm to 500 nm). The sidewall portions 12 may have an average thickness of 1 nm or more and 3 nm or less (i.e., from 1 nm to 3 nm). The columnar structures 10 may have an average equivalent circle diameter of 10 nm or more and 30 nm or less (i.e., from 10 nm to 30 nm).

The body portion 11 contains Fe (iron) and Co (cobalt), and the sidewall portion 12 contains Fe, Co, Si (silicon), and B (boron). The metal magnetic thin film 100 of the present disclosure is characterized in that the sidewall portion 12 of the columnar structure 10 contains more Fe and Co than Si and B in atomic percent (at %) concentration. That is, the sidewall portion 12 of the columnar structure 10 may have conductive or semiconductive properties rather than insulating properties. Preferably, the total amount of Fe and Co in the sidewall portion 12 is 35 at % or more. The atomic percent concentration refers to the percentage of the content of each element when the total amount of Fe, Co, Si, B, and P is 100 at %.

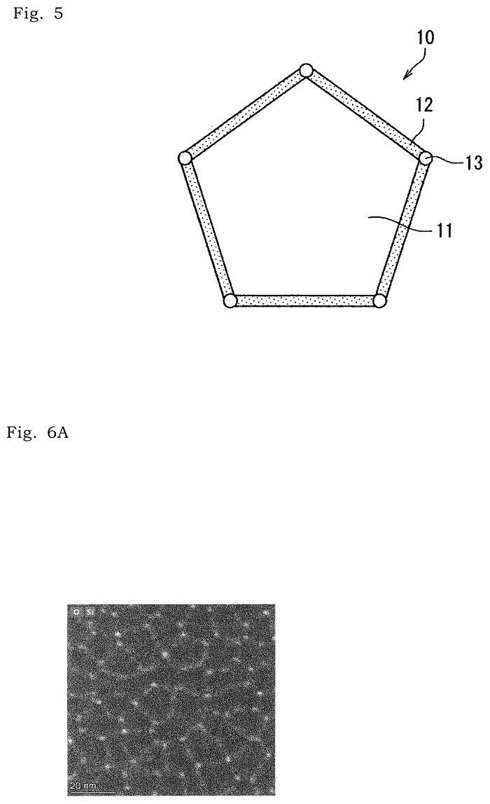

Furthermore, in the columnar structure 10, Si and B may be present in larger amounts in terms of atomic % concentration in the sidewall portion 12 than in the body portion 11. In particular, B may be present in a relatively larger amount in terms of atomic % concentration in the corner portion 13 of the sidewall portion 12 than in the other portions of the sidewall portion 12 (see FIGS. 4 and 5). Similarly, Si may be present in a relatively larger amount in terms of atomic % concentration in the corner portion 13 of the sidewall portion 12 than in the other portions of the sidewall portion 12.

According to the above feature, the sidewall portion 12 of the columnar structure 10 contains more Fe and Co than Si and B in terms of atomic percent concentration, thereby ensuring high saturation magnetization in the columnar structure 10. Therefore, the metal magnetic thin film 100 having a configuration in which a plurality of such columnar structures 10 are arranged in succession can ensure high saturation magnetization as a whole. The metal magnetic thin film 100 of the present disclosure may be able to achieve a Bs of about 1.7 T, preferably about 1.8 T.

Without being bound by any particular theory, it is believed that in the above-described columnar structure 10, light elements (such as B and Si) that are not part of the magnetic composition are expelled toward the sidewall portion 12 during the film formation process. Based on this, it is believed that, compared to a single amorphous phase without a columnar structure, the magnetic concentration in the body portion 11 is higher, the coordination number of the magnetic atoms (Fe, Co) closest to the Fe atom is larger, and the proportion of atomic pairs having components of α-Fe(Ms=2.15 T) and Fe0.5Co0.5 alloy (called permendur/Ms=2.45 T) with high saturation magnetization is increased. As a result, it is understood that an increase in Bs was achieved overall.

Furthermore, even if the thickness of the metal magnetic thin film 100 is relatively small, the columnar structures 10 can ensure high saturation magnetization, so that the metal magnetic thin film 100 can also be made thinner.

Furthermore, the metal magnetic thin film 100 of the present disclosure, which contains a Co component, can have columnar structures 10, compared to a film not containing a Co component. The columnar structures 10 have their longitudinal directions extending in the film thickness direction of the metal magnetic thin film 100, and therefore can be arranged perpendicular to the film extending direction of the metal magnetic thin film 100.

Such an arrangement can make it easier to form an easy axis that is easily magnetized in a direction perpendicular to the extension direction of the magnetic film 100 (thickness direction), while making it easier to form a hard axis that is difficult to magnetize in the extension direction of the magnetic film 100.

Specifically, the in-plane uniaxial anisotropy magnetic field Hk may be closely related to the demagnetizing factor Nd. Hk may become larger in the direction in which the demagnetizing factor Nd is large (the direction in which magnetization is difficult). The demagnetizing factor Nd may have the property that the sum of the x-, y-, and z-direction components is 1 (i.e., Ndx+Ndy+Ndz=1).

When the magnetic film is in the form of a thin film, the demagnetizing factor Nd is usually approximately 1 in the film thickness (z) direction and approximately 0 in the in-plane (x, y) directions, and the in-plane anisotropy magnetic field can be relatively small. In contrast, the metal magnetic thin film 100 of the present disclosure includes, as its constituent, columnar structures 10 whose longitudinal axes extend in the film thickness direction, so that the demagnetizing factor (Nd) can be approximately 0 in the film thickness (z) direction and approximately 0.5 and approximately 1 in the in-plane (x, y) directions, respectively.

When plural such columnar structures 10 are arranged adjacent to each other, that is, when the metal magnetic thin film 100 has a structure in which plural columnar structures 10 are arranged in parallel along the film thickness direction, the demagnetizing factor in the film thickness direction (corresponding to the direction perpendicular to the film) approximates 0. On the other hand, the demagnetizing factor in the direction of the film extension surface approximates 1.

As a result, the demagnetizing factor becomes large in the film extension direction (corresponding to the xy plane direction) of the magnetic film 100, making it easier to form a hard axis, and making it possible to relatively increase the anisotropy field (Hk) in the film extension direction (corresponding to the xy plane direction) of the magnetic film 100. Therefore, with the metal magnetic thin film 100 of the present disclosure, it is possible to achieve both high saturation magnetization and in-plane uniaxial anisotropy.

In the metal magnetic thin film 100 of the present disclosure, the sidewall portions 12 of the columnar structures 10, which are its constituent, contain Si, which makes it possible to increase the resistance value of the sidewall portions 12. As a result, when plural columnar structures 10 can be arranged continuous with one another as described above inside the metal magnetic thin film 100, a structure can be formed in which a large number of resistive sidewall portions are arranged in series in the direction in which eddy currents are generated. Thus, it is possible to increase the resistance value of the metal magnetic thin film 100 as a whole.

The metal magnetic thin film 100 of the present disclosure preferably further contains P (phosphorus). Compared to a case where no P is contained, when P is further contained in the metal magnetic thin film 100 having amorphous columnar structures, the corrosion resistance of the film surface can be improved even when left in the atmosphere for a long period of time. The atomic percent concentration of P may be higher in the sidewall portion than in the body portion.

Without being bound by any particular theory, it is believed that the metal magnetic thin film 100 containing Fe and P reacts with oxygen on the film surface, forming iron phosphate or the like on the film surface, which can function as a corrosion-resistant film, thereby improving the corrosion resistance of the film surface as described above.

It should be noted that when P is present at the grain boundaries of a crystalline material rather than an amorphous material, corrosion of the grain boundaries may occur. However, since the columnar structure that forms the base of the metal magnetic thin film 100 of the present disclosure is amorphous, the above grain boundaries are unlikely to be clearly formed, and the above corrosion is unlikely to occur.

The metal magnetic thin film 100 of the present disclosure may have the following composition irrespective of the presence or absence of P (phosphorus).

$$\begin{matrix}( Fe 1 - x Co x ) a Si b ( B 1 - y P y ) c \\ a + b + c = 100 at \% \\ 82 \leq a \leq 86.2 \\ 0 < b \leq 2 \\ 12 \leq c \leq 17.2 \\ 0 < x \leq 0.95 ( more preferability 0.1 \leq x \leq 0.6 ) \\ 0 \leq y < 1 ( y = 0.3 is preferred )\end{matrix}$$

The composition of the metal magnetic thin film can be determined by dissolving the thin film to form a solution and then performing ICP analysis. The oxygen content in the metal magnetic thin film is preferably 3 at % or less.

The metal magnetic thin film 100 of the present disclosure can be disposed between insulating films 150 on a Si substrate 160 with a thermal oxide film (see FIG. 9). Specifically, as one example, the insulating films 150 and the metal magnetic thin films 100 can be alternately stacked. As another example, the metal magnetic thin film 100 can be disposed between the insulating films 150.

In this case, the insulating film may be made of a material containing at least one of aluminum oxide, silicon oxide, aluminum nitride, silicon nitride, magnesium oxide, and zirconium oxide. The insulating film preferably has a low dielectric constant. The dielectric constant is preferably 10 or less, more preferably 8 or less, and even more preferably 4 or less. Furthermore, when forming a laminated structure, it is preferable that the interface between the magnetic film and the insulating film be substantially flat.

The insulating film 150 may have an average thickness of 1 nm to 20 nm, preferably 15 nm.

### [Electronic Component Manufacturing Method]

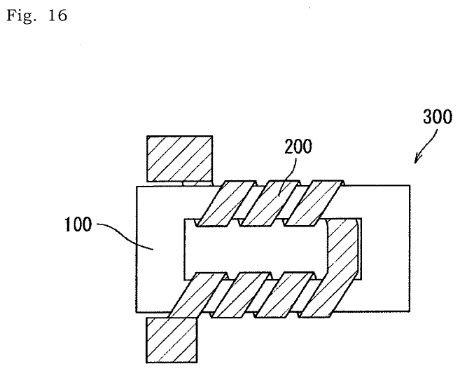

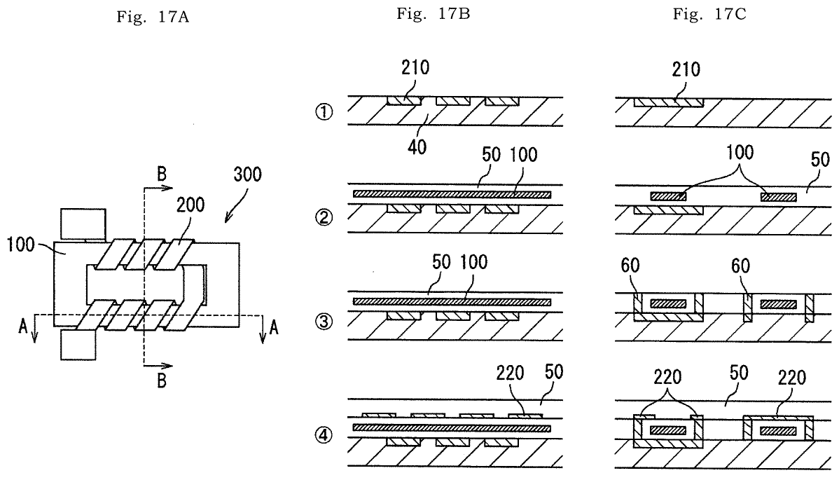

An example of a manufacturing method for an electronic component 300 including a metal magnetic thin film 100 according to the present disclosure will be described below with reference to FIG. 16 and FIGS. 17A to 17C. FIG. 17A is a schematic diagram showing the structure of the electronic component 300. FIG. 17B is a diagram corresponding to the A-A cross section of the electronic component 300 in FIG. 17A. FIG. 17C is a diagram corresponding to the B-B cross section of the electronic component 300 in FIG. 17A. Note that the insulating film covering the surface of a coil conductor 200 is omitted in FIG. 17A.

(1) First, photolithography is used to pattern a resist into a desired shape on a support substrate 40 such as a silicon substrate or a glass substrate. An opening in the resist is etched to a desired depth using RIE or other techniques. Next, a conductor such as Cu is embedded in the etched area by plating or other methods, and the resist is removed to form a lower coil 210.

(2) Next, an insulating film 50 made of photoresist resin or SiO2 or the like is formed on the entire surface of the support substrate, including the surface of the lower coil 210. A metal magnetic thin film 100 is formed on this insulating film 50 using a method such as sputtering. After patterning the resist, excess metal magnetic thin film 100 is removed by RIE or ion milling or the like. After removing the resist, the insulating film 50 is formed so as to cover the entire surface of the magnetic thin film 100.

(3) Next, resist is patterned to form openings corresponding to desired locations of the lower coil 210. The insulating film 50 is etched down to the lower coil 210 by RIE or the like. A conductor such as Cu is embedded in the etched locations by plating or the like to form pillars 60 that connect the lower coil 210 and an upper coil 220, which will be described later, and the resist is then removed.

Next, after patterning the resist, a conductor such as Cu is embedded in the openings to form the upper coil 220. After removing the resist, the insulating film 50 is formed so as to cover the entire surface of the upper coil 220. In this manner, the electronic component 300 can be manufactured.

### EXAMPLES

Examples will be described below.

### Example 1

Using a sputtering device (Canon Anelva Corporation, Model EC7400), a 15 nm SiN insulating film was sputter-deposited as an adhesion layer on a 0.7 μm-thick Si substrate with a thermal oxide film. While maintaining a vacuum, a 200 nm amorphous metal magnetic thin film was sputter-deposited on the SiN insulating film. A target with a composition of (Fe_{0.75}Co_{0.25})₈₆Si₁B₁₃ was used as the magnetic material for the metal magnetic thin film. A unidirectional magnetic field was applied parallel to the Si substrate during the sputtering deposition process.

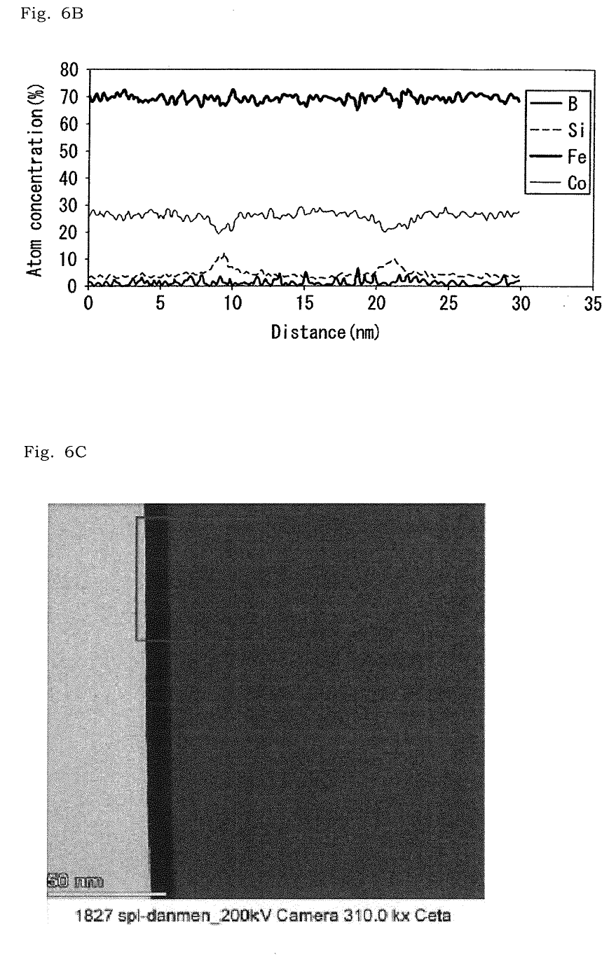

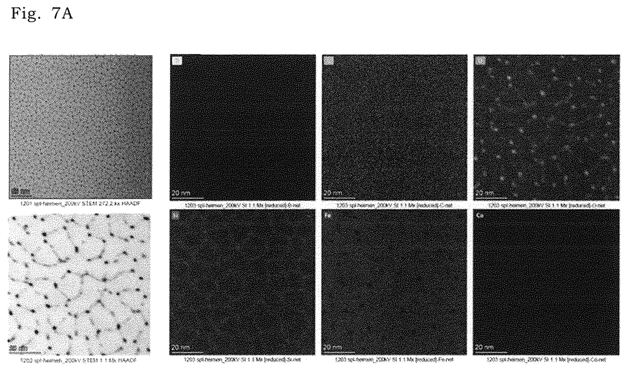

The surface of this amorphous magnetic metal thin film was captured at a predetermined location in a direction parallel to the substrate using a scanning transmission electron microscope, and the image is shown in FIG. 6A. EDX line analysis was also performed along line A in FIG. 6A, and the analysis results are shown in FIG. 6B. The scanning transmission electron microscope was also used to capture a cross section of the metal magnetic thin film along the thickness direction at a predetermined location, and the image (i.e., equivalent to a cross-sectional image) is shown in FIG. 6C.

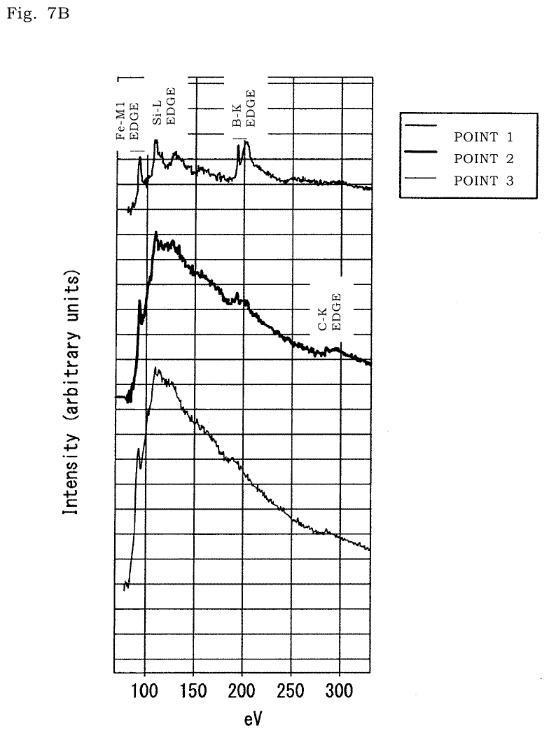

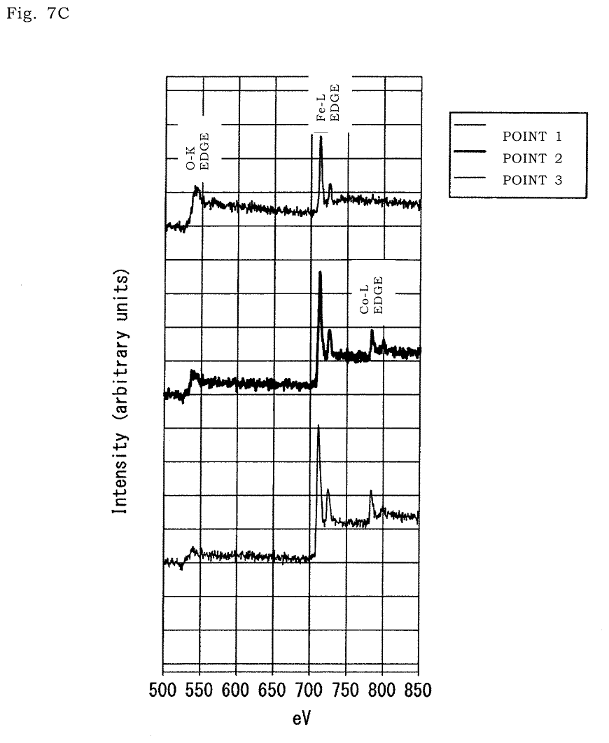

FIG. 7A shows an image (STEM image) of a surface at a predetermined location of the metal magnetic thin film obtained through a similar process, taken using a scanning transmission electron microscope in a direction parallel to the substrate, and an element mapping image obtained using an EDX analyzer (energy dispersive X-ray fluorescence analyzer). Specifically, the metal magnetic thin film was irradiated with X-rays using the EDX analyzer, and the energy or wavelength and intensity of the fluorescent X-rays generated were analyzed to analyze the types of elements constituting the thin film.

From FIGS. 6A and 7A, it was found that each columnar structure of the amorphous metal magnetic thin film has a body portion and a sidewall portion continuous therewith. From FIG. 6C, it was found that the amorphous metal magnetic thin film has a plurality of columnar structures that are continuous with or adjacent to each other. From FIG. 6B, it was found that the total amount of Fe and Co is greater than the total amount of Si and B in atomic percent concentration in both the body portion and the sidewall portion of the columnar structure. That is, it was found that the total amount of Fe and Co is greater than the total amount of Si and B in atomic percent concentration in both the body portion and the sidewall portion of the columnar structure. Note that the portion in FIG. 6B where the amount of Co is locally reduced corresponds to the sidewall portion.

As shown in FIG. 7A, the presence of Fe, Co, Si, etc., which are elements constituting the target of the metal magnetic thin film (sputtered film), was confirmed in the area corresponding to the STEM image. Specifically, the presence of Fe, Co, and Si was confirmed in the body and sidewall portions 12 of the columnar structures that constitute the metal magnetic thin film.

Since B (boron) could not be confirmed in the element mapping image, EELS spectra were measured at three points in the STEM image of FIG. 7A based on electron energy loss spectroscopy (EELS). This measurement method involves irradiating a metal magnetic thin film with an electron beam and measuring the energy lost when the electron beam excites electrons in the thin film, thereby analyzing the thin film composition and the bonding state of the elements. The measurement results are shown in FIGS. 7B and 7C.

Point 1 is a corner portion of the sidewall of the columnar structure (corresponding to the dark dots in the STEM image in FIG. 7A). Point 2 is a linear portion between the corner portions of the sidewall of the columnar structure (corresponding to the linear portion connecting the dark dots in the STEM image in FIG. 7A). Point 3 is a body portion located inside the sidewall portion 12 of the columnar structure.

As shown in FIGS. 7B and 7C, based on the measurement results of points 1 and 2, it was confirmed that there were peaks for not only Fe, Co, and Si but also B in the sidewall portion of the columnar structure. It was found that B was locally distributed unevenly at point 1. STEM electron diffraction confirmed that the body portion was amorphous. Furthermore, as a result of an analysis similar to that of FIG. 6B, it was found that the total amount of Fe and Co was greater than the total amount of Si and B in terms of atomic percent concentration not only in the body portion but also in the sidewall portion of the columnar structure.

### Example 2

Using a sputtering device (Canon Anelva Corporation, Model EC7400), a 15 nm SiN insulating film was sputter-deposited as an adhesion layer on a 0.7 μm-thick Si substrate with a thermal oxide film. While maintaining a vacuum, five layers of 200 nm amorphous metal magnetic thin film and five layers of 15 nm SiN insulating film were alternately sputter-deposited on the SiN insulating film. A target with a composition of (Fe_{0.5}Co_{0.5})₈₆Si₁B₁₃ was used as the magnetic material for the metal magnetic thin film. The final SiN insulating film also served as a corrosion-protection cover layer.

During the sputtering film formation process, a magnetic field is applied in one direction parallel to the Si substrate.

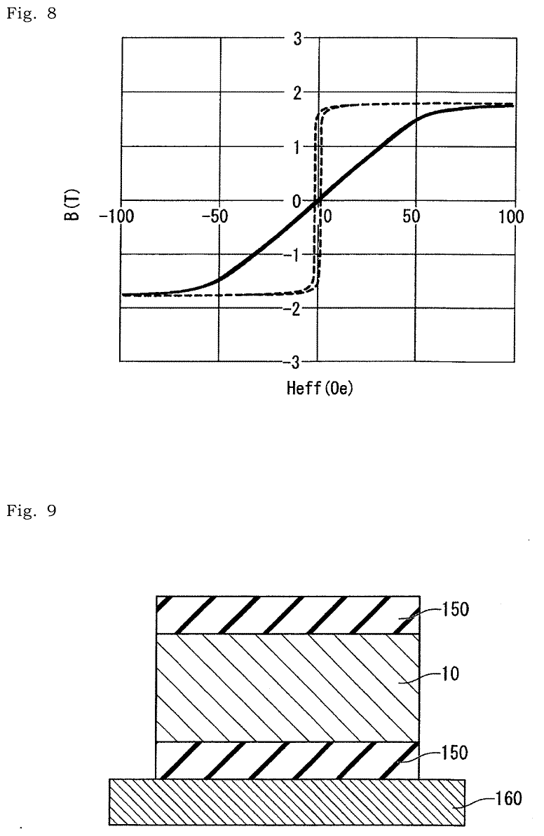

A graph of the magnetization curve of the resulting laminate including the metallic magnetic thin film is shown in FIG. 8. From the results in FIG. 8, it was found that Hk=58.4 Oe, Bs=1.8 T, and Hc=0.5 Oe.

FIG. 8 shows the results of measurements using a VSM (vibrating sample magnetometer). In FIG. 8, the solid line indicates the hard axis direction, and the dotted line indicates the measurement results in the easy axis direction. The results in FIG. 8 show a significant difference in magnetic properties, indicating the presence of in-plane uniaxial anisotropy.

### Example 3-1

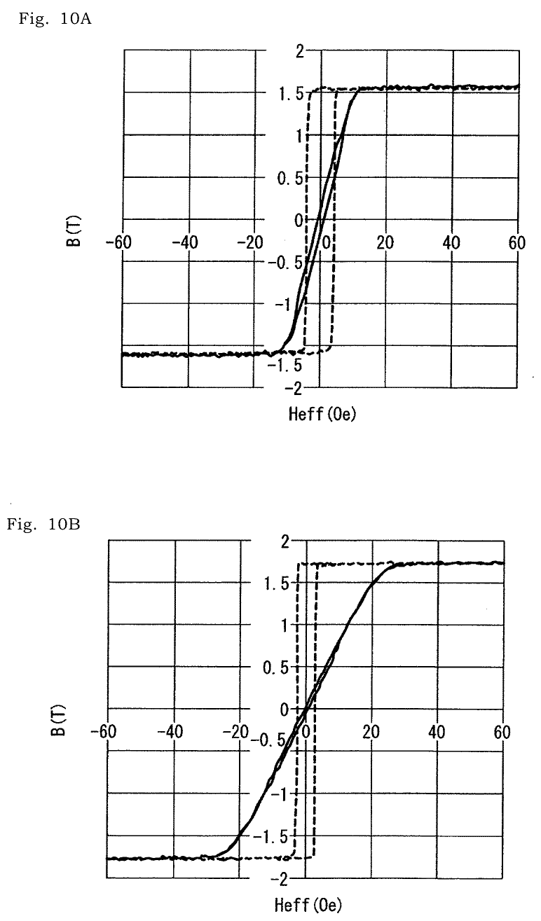

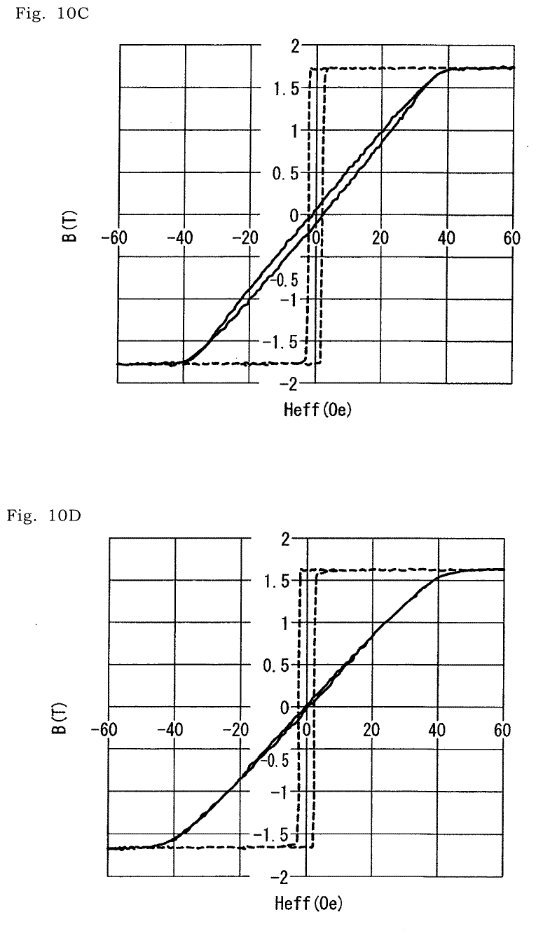

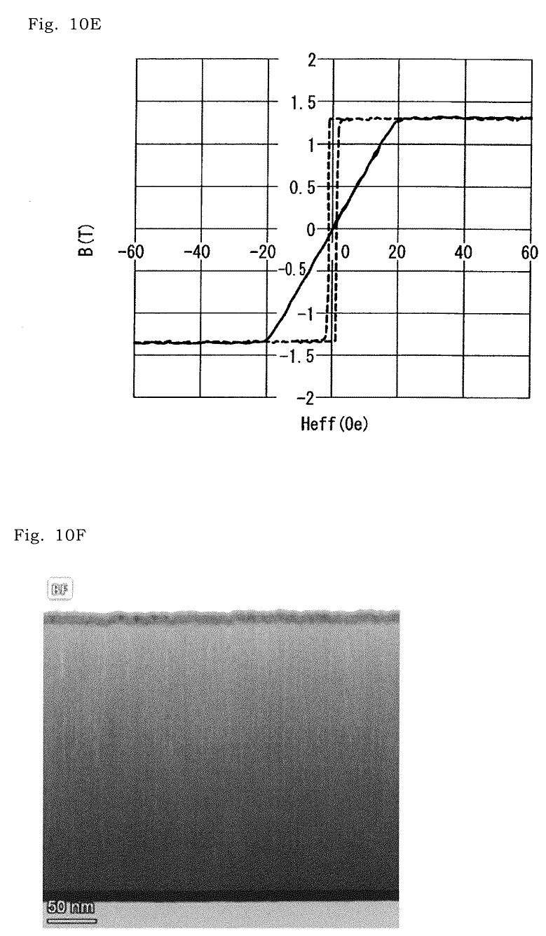

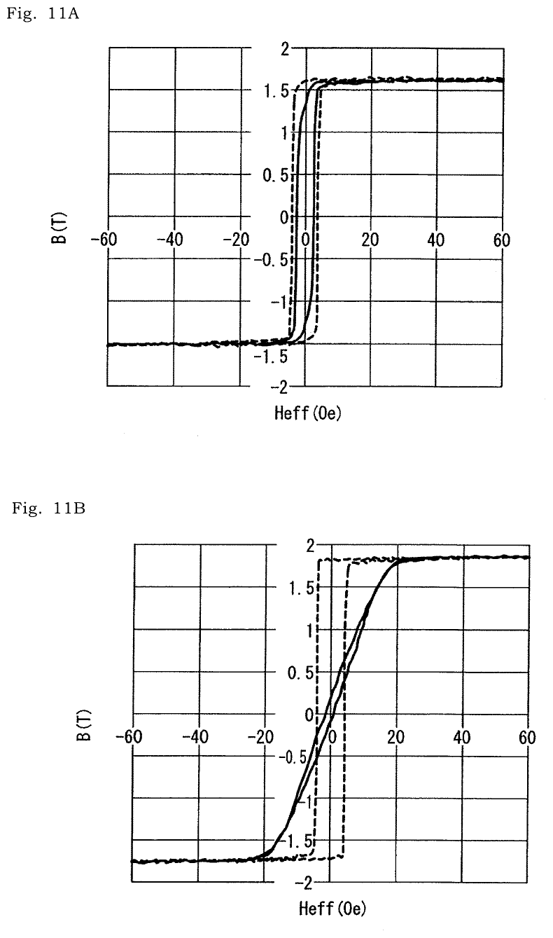

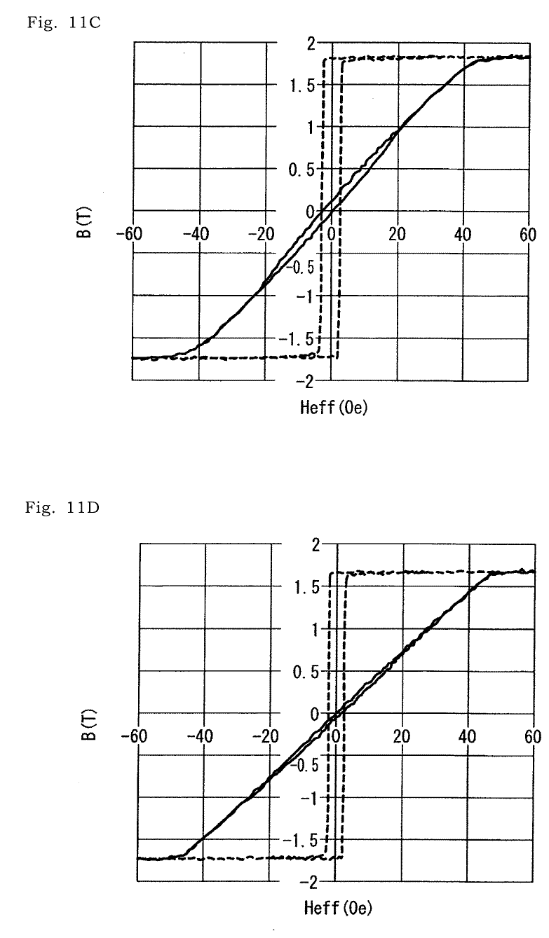

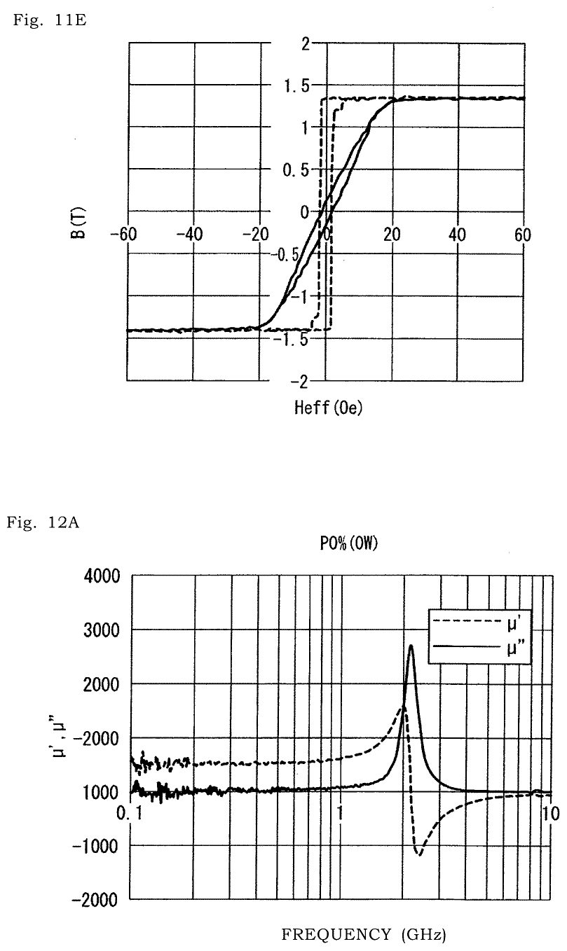

A sputtering apparatus was used to deposit a 5 nm SiN insulating film 150 as an adhesion layer on a thermally oxidized Si substrate 160. Under vacuum conditions, an amorphous metal magnetic thin film 100 of a predetermined thickness was sputter-deposited on the SiN insulating film 150. A target having a composition of (Fe₁₋ₓCoₓ)₈₆Si₁B₉P₄ was used as the magnetic material for the metal magnetic thin film. While maintaining the vacuum, a 5 nm SiN insulating film 150 was deposited thereon to form a laminated film (see FIG. 9). A unidirectional magnetic field was applied parallel to the Si substrate during the sputter deposition process. The magnetization curves for this case are shown in FIGS. 10A to 10E. Furthermore, a cross section at a predetermined location along the thickness direction of the metal magnetic thin film when the Co content was 50 at % was captured, and the resulting image (i.e., a cross-sectional image) is shown in FIG. 10F. In addition to forming the laminated film, a reflow treatment was performed three times at 260 degrees for one minute. The results of the magnetization curves in this case are shown in FIGS. 11A to 11E.

In this Example 3-1, the Co content of the magnetic material used was varied in plural ways, and the behavior of the magnetization curve for each was confirmed. FIGS. 10A to 10E show magnetization curves for a 40 nm film thickness where the Co content was set to 0 at %, 10 at %, 30 at %, 50 at %, and 100 at %, respectively, when the total amount of Fe and Co was 100 at %. FIGS. 11A to 11E show magnetization curves for a 40 nm film thickness where additional reflow processing was performed, where the Co content was set to 0 at %, 10 at %, 30 at %, 50 at %, and 100 at %, respectively, when the total amount of Fe and Co was 100 at %.

The measurement results in FIGS. 10A to 10E show that the anisotropy magnetic field Hk is better secured when Co is included in the metal magnetic thin film than when Co is not included. Furthermore, the measurement results in FIGS. 11A to 11E show that the Hk is secured and the thermal stability of the anisotropy magnetic field is improved when Co is included in the metal magnetic thin film, even after additional reflow processing, i.e., heat treatment, compared to when Co is not included in the metal magnetic thin film. Furthermore, a similar stacked film was fabricated with a Co content of 95 at % when the total amount of Fe and Co is 100 at %. Measurement of the magnetic properties revealed a Bs of 1.3 T or more. Furthermore, FIG. 10F shows that the amorphous metal magnetic thin film has plural columnar structures that are continuous with or adjacent to each other.

### Example 3-2

A sputtering apparatus was used to deposit a 10 nm thick Ta film as an adhesion layer on a Si substrate with a thermal oxide film. Under vacuum conditions, an amorphous, 40 nm thick metal magnetic thin film 100 was sputter-deposited on the Ta film. A target having a composition of (Fe_{0.75}Co_{0.25})₈₄Si₂B_{14-z}P_{z} (z=0, 2.0, 4.4, 7.1, 14.0) was used as the magnetic material used in the metal magnetic thin film. While maintaining the vacuum, a 10 nm thick Ta film was deposited thereon to form a laminated film. A unidirectional magnetic field was applied parallel to the Si substrate during the sputtering deposition process.

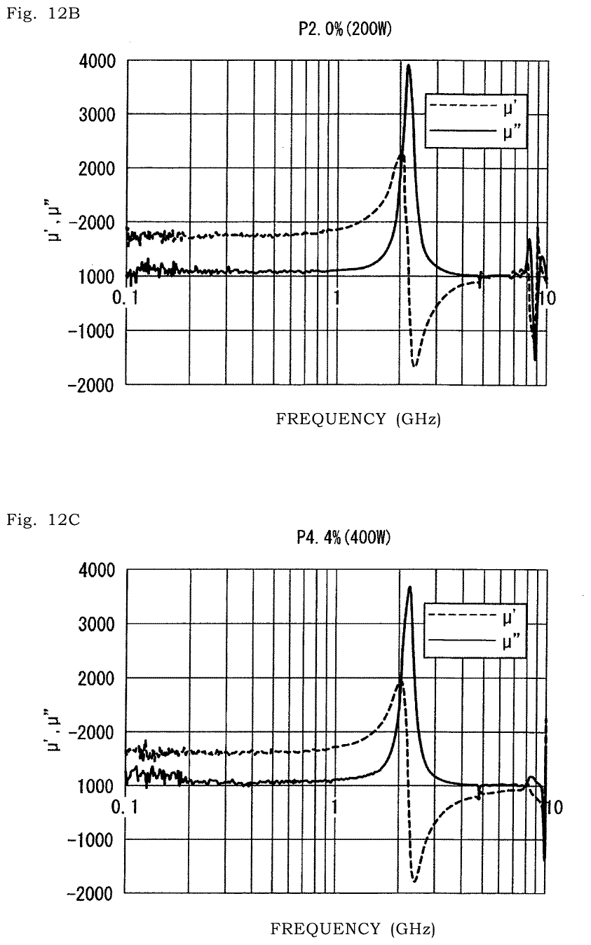

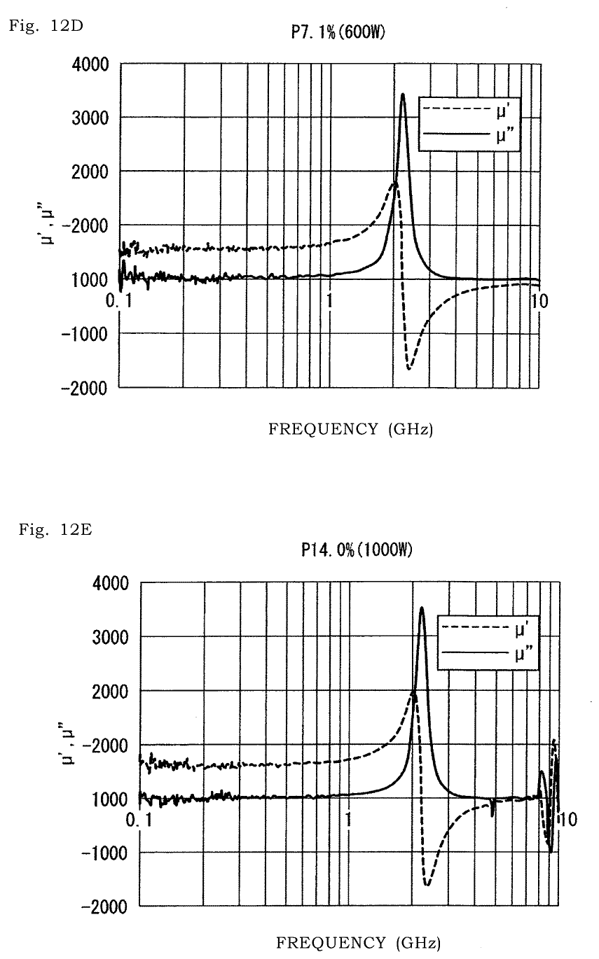

In the case where the thickness of the metal magnetic thin film was 40 nm, the behavior of the real part μ′ and the imaginary part μ″ of the complex permeability with respect to frequency was measured depending on the P content in the thin film. The results are shown in FIGS. 12A to 12E. The permeability was measured using a high-frequency permeability measuring device manufactured by Keycom Corporation.

Specifically, measurements were performed by exciting the sample in the direction of the hard axis of magnetization in the range of 100 MHz to 16 GHz. FIGS. 12A to 12E show that, compared to FIG. 12A, which does not contain P (phosphorus), FIGS. 12B to 12E, which contain a specified proportion of phosphorus, show that the imaginary part μ″ of the magnetic permeability shifts toward higher frequencies, making it possible to reduce the ratio of the real part of the magnetic permeability to the imaginary part of the magnetic permeability (μ″/μ′), and ensuring in-plane uniaxial anisotropy. In other words, it was found that when the obtained metal magnetic thin film contains a specified proportion of P (phosphorus), it can provide excellent magnetic properties in the high-frequency range.

### Example 3-3

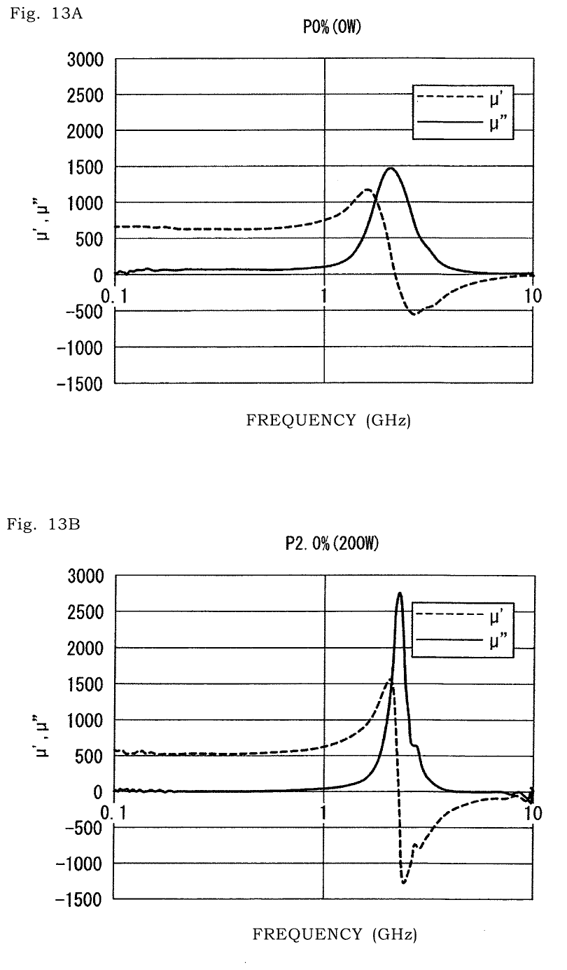

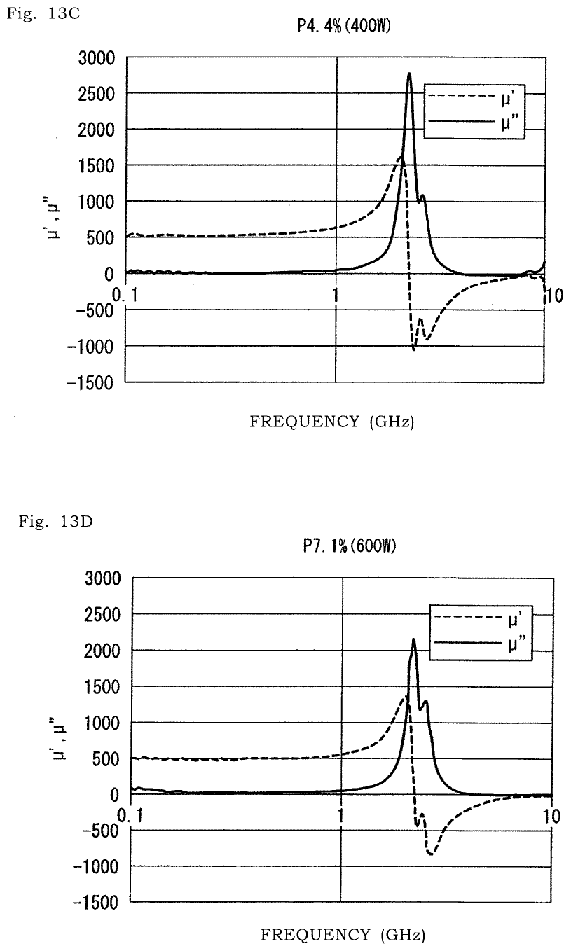

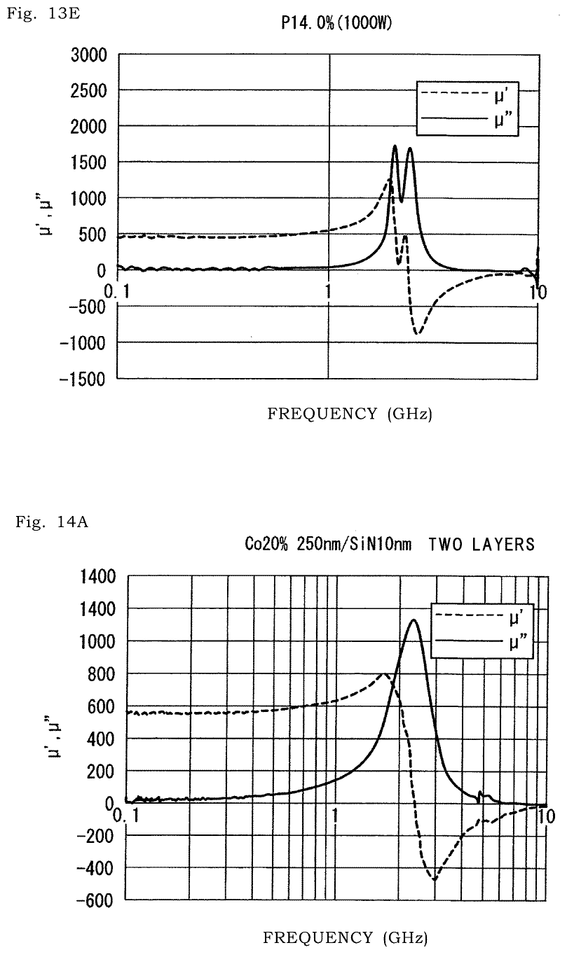

Furthermore, when the thickness of the metal magnetic thin film was 160 nm, the behavior of the real part μ′ and the imaginary part μ″ of the complex permeability with respect to frequency was measured depending on the P content in the thin film. The results are shown in FIGS. 13A to 13E. The permeability was measured using a high-frequency permeability measuring device manufactured by Keycom, as described above.

Specifically, measurements were performed by exciting the sample in the direction of the hard axis of magnetization in the range of 100 MHz to 16 GHz. From FIGS. 13A to 13E, it was found that, compared to FIG. 13A, which does not contain P (phosphorus), FIGS. 13B to 13E, which contain a specified proportion of phosphorus, show that the imaginary part μ″ of the magnetic permeability shifts toward higher frequencies, making it possible to reduce the ratio of the real part of the magnetic permeability to the imaginary part of the magnetic permeability (μ″/μ′), and ensuring in-plane uniaxial anisotropy. In other words, it was found that even when the resulting metal magnetic thin film has a thickness of 160 nm, containing a specified proportion of P (phosphorus) can provide excellent magnetic properties in the high-frequency range.

The amorphous structure was confirmed by STEM electron diffraction. As a result of observation by a scanning transmission electron microscope and EDX line analysis similar to those in Example 1, it was found that the metal magnetic thin film had a plurality of columnar structures, and that the total amount of Fe and Co was greater than the total amount of Si and B in terms of atomic percent concentration in both the body and sidewall portions of the columnar structures.

### Example 4

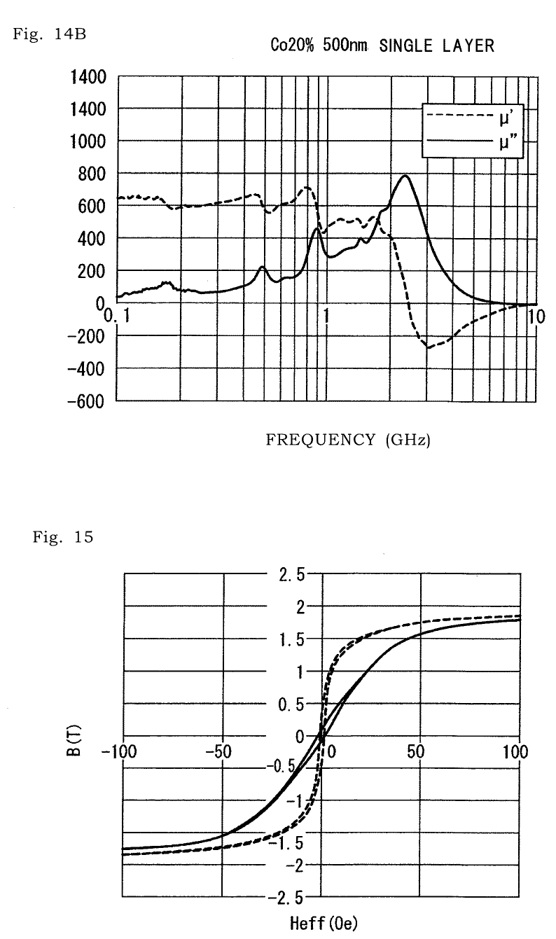

A 10 nm SiN insulating film was deposited as an adhesion layer on an Si substrate with a thermal oxide film (0.7 μm thick) using a sputtering device. A target with a composition of (Fe_{0.8}Co_{0.2})₈₆Si₁B₉P₄ was used as the magnetic material. While maintaining a vacuum, two cycles of sputtering were performed on the SiN insulating film, combining a 250-nm amorphous metal magnetic thin film and a 10-nm SiN interlayer insulating film, forming a 0.5-μm magnetic film stack (pattern shown in FIG. 14A). The SiN insulating film deposited between the amorphous metal magnetic thin films functions as an interlayer insulating film. A unidirectional magnetic field was applied parallel to the substrate during sputtering. In addition, a specified stacked film was also formed without the interlayer insulating film. A 10 nm SiN insulating film was deposited as an adhesion layer on a Si substrate with a thermal oxide film (0.7 μm thick). While maintaining the vacuum state, a 500 nm amorphous magnetic metal thin film was sputter-deposited on the SiN insulating film. A target with a composition of (Fe_{0.8}Co_{0.2})₈₆Si₁B₉P₄ was used as the magnetic material. Finally, a 10 nm SiN insulating film was continuously deposited (pattern shown in FIG. 14B).

The behavior of the real part μ′ and imaginary part μ″ of the complex permeability versus frequency for the obtained laminated film is shown in FIGS. 14A and 14B, respectively. The measurement results in FIGS. 14A and 14B show that without an interlayer insulating film, losses due to eddy currents occur, causing the frequency curve to become distorted. On the other hand, with the presence of an interlayer insulating film, the generation of eddy currents is suppressed, resulting in a stable frequency curve. Regardless of the presence or absence of an interlayer insulating film, in-plane uniaxial anisotropy and high saturation magnetization were obtained in all cases.

### Example 5

Using a sputtering device, a 15 nm SiN insulating film was deposited as an adhesion layer on a Si substrate coated with a 10 μm-thick polyimide resin (coated and baked). A target with a composition of (Fe_{0.7}Co_{0.3})₈₆Si₁B₉P₄ was used as the magnetic material. While maintaining vacuum, a combination of a 250 nm amorphous metal magnetic film and a 5 nm SiN interlayer insulating film was repeatedly deposited on the SiN insulating film for 20 cycles, resulting in a 5 μm magnetic film stack. The final SiN insulating film also served as a corrosion protection cover layer. A unidirectional magnetic field was applied parallel to the substrate during sputtering.

The behavior of the magnetization curve of the obtained laminate was confirmed. The results are shown in FIG. 15. From the measurement results in FIG. 15, it was found that in-plane uniaxial anisotropy was ensured even when using a Si substrate on which a 10 μm-thick polyimide resin was formed. It was also found that Hk=27.8 Oe, Bs=1.75 T, and Hc=1.5 Oe.

The present disclosure includes, but is not limited to, the following aspects.
<1> A metal magnetic thin film, comprising a plurality of columnar structures having an amorphous phase and whose longitudinal directions extend in a film thickness direction. The plurality of columnar structures each include a body portion and a sidewall portion continuous with the body portion. The plurality of columnar structures each contain Fe, Co, Si, and B. Also, in the sidewall portion, the total amount of the Fe and the Co is greater than the total amount of the Si and the B in terms of atomic percent concentration.
<2> The metal magnetic thin film according to <1>, wherein the sidewall portion is a conductor or a semiconductor.
<3> The metal magnetic thin film according to <1> or <2>, wherein the metal magnetic thin film has uniaxial anisotropy in a plane of the thin film.
<4> The metal magnetic thin film according to any one of <1> to <3>, further comprising P.
<5> The metal magnetic thin film according to any one of <1> to <4>, wherein the atomic percent concentration of Si in the sidewall portion is greater than the atomic percent concentration of Si in the body portion.
<6> The metal magnetic thin film according to any one of <1> to <5>, wherein the atomic percentage of B in the sidewall portion is greater than the atomic percentage of B in the body portion.
<7> The metal magnetic thin film according to any one of <1> to <6>, wherein the plurality of columnar structures each have a polygonal shape when viewed in plan view from the film thickness direction. Also, each of the polygonal columnar structures has a plurality of corner portions in the sidewall portion, and the plurality of corner portions each contain a relatively larger amount of B in terms of atomic % concentration than portions other than the corner portions in the sidewall portion.
<8> The metal magnetic thin film according to any one of <1> to <7>, wherein the atomic percentage concentrations of the Fe and the Co are higher in the body portion than in the sidewall portion.
<9> The metal magnetic thin film according to any one of <1> to <7>, wherein the metal magnetic thin film is a sputtered film.
<10> The metal magnetic thin film according to any one of <1> to <9>, wherein the metal magnetic thin film has an average thickness of 100 nm or more and 500 nm or less (i.e., from 100 nm to 500 nm).
<11> The metal magnetic thin film according to any one of <1> to <10>, wherein the sidewall portion has an average thickness of 1 nm or more and 3 nm or less (i.e., from 1 nm to 3 nm).
<12> The metal magnetic thin film according to any one of <1> to <11>, wherein the plurality of columnar structures each have an average equivalent circle diameter of 10 nm or more and 30 nm or less (i.e., from 10 nm to 30 nm).
<13> An electronic component comprising the metal magnetic thin film according to any one of <1> to <12>; and an insulating film disposed on both sides of the metal magnetic thin film in a stacking direction.
<14> The electronic component according to <13>, wherein the electronic component is an inductor.

Although the embodiments of the present disclosure have been described hereinabove, they are merely typical examples. Those skilled in the art will readily understand that the present disclosure is not limited thereto, and that various modifications are possible without departing from the spirit of the present disclosure

The metal magnetic thin film of the present disclosure can be suitably used in a wide range of applications, such as high frequency applications in electronic components and the like.

What is claimed is:

1. A metal magnetic thin film, comprising:
a plurality of columnar structures having an amorphous phase and whose longitudinal directions extend in a film thickness direction,
the plurality of columnar structures each including a body portion and a sidewall portion continuous with the body portion,
the plurality of columnar structures each comprising Fe, Co, Si, and B, wherein
in the sidewall portion, a total amount of the Fe and the Co is greater than a total amount of the Si and the B in terms of atomic percent concentration.

2. The metal magnetic thin film according to claim 1, wherein
the sidewall portion is a conductor or a semiconductor.

3. The metal magnetic thin film according to claim 1, wherein
the metal magnetic thin film has uniaxial anisotropy in a plane of the thin film.

4. The metal magnetic thin film according to claim 1, further comprising P.

5. The metal magnetic thin film according to claim 1, wherein
an atomic percent concentration of Si in the sidewall portion is greater than an atomic percent concentration of Si in the body portion.

6. The metal magnetic thin film according to claim 1, wherein
an atomic percentage of B in the sidewall portion is greater than an atomic percentage of B in the body portion.

7. The metal magnetic thin film according to claim 1, wherein
the plurality of columnar structures each have a polygonal shape when viewed in plan view from the film thickness direction, wherein
each of the polygonal columnar structures has a plurality of corner portions in the sidewall portion, and wherein
the plurality of corner portions each comprises a relatively larger amount of B in terms of atomic % concentration than portions other than the corner portions in the sidewall portion.

8. The metal magnetic thin film according to claim 1, wherein
atomic percentage concentrations of the Fe and the Co are higher in the body portion than in the sidewall portion.

9. The metal magnetic thin film according to claim 1, wherein
the metal magnetic thin film is a sputtered film.

10. The metal magnetic thin film according to claim 1, wherein
the metal magnetic thin film has an average thickness of from 100 to 500 nm.

11. The metal magnetic thin film according to claim 1, wherein
the sidewall portion has an average thickness of from 1 nm to 3 nm.

12. The metal magnetic thin film according to claim 1, wherein
the plurality of columnar structures each have an average equivalent circle diameter of from 10 nm to 30 nm.

13. An electronic component comprising:
the metal magnetic thin film according to claim 1; and
an insulating film on both sides of the metal magnetic thin film in a stacking direction.

14. The electronic component according to claim 13, wherein
the electronic component is an inductor.
